(19) United States
(12) Patent Application Publication
(10) Pub. No.: US 2026/0230062 A1
(43) Pub. Date: Aug. 6, 2026

(54) NOTCH FILTER CIRCUIT WITH ALL-PASS FILTER FOR INDEPENDENT CONTROL OF FILTER GAIN AND QUALITY FACTOR

(71) Applicant: QUALCOMM Incorporated, San Diego, CA (US)

(72) Inventors: Vahid DABBAGH REZAEI, San Diego, CA (US); Ahmed ABBAS MOHAMED HELMY, San Diego, CA (US)

(21) Appl. No.: 19/046,719

(22) Filed: Feb. 6, 2025

(51) Int. Cl. H03H 11/04

(52) U.S. Cl. CPC H03H 11/04; H03H 2011/0488

(57) ABSTRACT

Techniques and apparatus for processing a signal using a filter circuit. One example filter circuit generally includes an input node; an output node; an amplifier including an output coupled to the output node of the filter circuit; a twin-T notch filter including a first node coupled to the input node of the filter circuit, a second node coupled to the output of the amplifier, and a third node coupled to a first input of the amplifier; and an all-pass filter coupled between the output of the amplifier and a second input of the amplifier. The inclusion of the all-pass filter in the filter circuit generally decouples the filter gain from the filter quality factor (Q), thereby enabling independent control of the gain and the Q of the filter circuit.

### TECHNICAL FIELD

Certain aspects of the present disclosure generally relate to electronic circuits and, more particularly, to notch filter circuits with independent control of filter gain and quality factor.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include transceiver circuitry, which may be used for processing (e.g., filtering, mixing, and amplifying) signals for transmission and reception, for example. The transceiver circuitry may include one or more filters, such as notch filters.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include independent control of filter gain and quality factor in a single-amplifier twin-T notch filter circuit. The single-amplifier twin-T notch filter circuit consumes less power and occupies less area than other notch filter circuits with similar performance.

Certain aspects of the present disclosure provide a filter circuit. The filter circuit generally includes an input node; an output node; an amplifier including an output coupled to the output node of the filter circuit; a twin-T notch filter including a first node coupled to the input node of the filter circuit, a second node coupled to the output of the amplifier, and a third node coupled to a first input of the amplifier; and an all-pass filter coupled between the output of the amplifier and a second input of the amplifier.

Certain aspects of the present disclosure provide a notch filter circuit. The notch filter circuit generally includes a single amplifier, the notch filter circuit being configured to independently control a quality factor of the notch filter circuit and a gain of the notch filter circuit.

Certain aspects of the present disclosure are directed to a method of signal processing. The method generally includes (i) receiving a signal at an input of a notch filter circuit comprising a single amplifier, the notch filter circuit being configured to control a quality factor of the notch filter circuit independently from a gain of the notch filter circuit, and (ii) filtering the signal using the notch filter circuit.

Certain aspects of the present disclosure are directed to a method of signal processing. The method generally includes (i) receiving a signal at an input of an active twin-T notch filter circuit comprising an amplifier and an all-pass filter coupled between an output of the amplifier and an input of the amplifier, and (ii) filtering the signal using the active twin-T notch filter circuit.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4A is a schematic diagram of an example filter circuit that includes an amplifier and a twin-T notch (TTN) filter and an associated frequency response with different gains, in accordance with certain aspects of the present disclosure.

FIG. 4B is a block diagram of an example filter circuit that includes an amplifier, a notch filter network, and an all-pass filter, in accordance with certain aspects of the present disclosure.

FIG. 4C is a schematic diagram of an example single-ended filter circuit that includes an amplifier, a TTN filter, and an all-pass filter and an associated frequency response with different gains, in accordance with certain aspects of the present disclosure.

FIG. 4D is a schematic diagram of an example differential filter circuit that includes a differential amplifier, two TTN filters, and two all-pass filters, in accordance with certain aspects of the present disclosure.

FIGS. 5 and 6 are flow diagrams of example operations for signal processing, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide a filter circuit (e.g., a single-amplifier twin-T notch filter circuit) with independent control of filter gain and quality factor (Q), which may be included in wireless receiver front-end circuitry. Such a filter circuit may include an amplifier, a notch filter network (e.g., a twin-T notch (TTN) filter) coupled to a first input (e.g., the positive input) of the amplifier, and an all-pass filter coupled between an output of the amplifier and a second input (e.g., the negative input) of the amplifier. The inclusion of the all-pass filter in the filter circuit may decouple the filter gain from the filter Q, thereby enabling independent control of the gain and the Q of the filter circuit.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

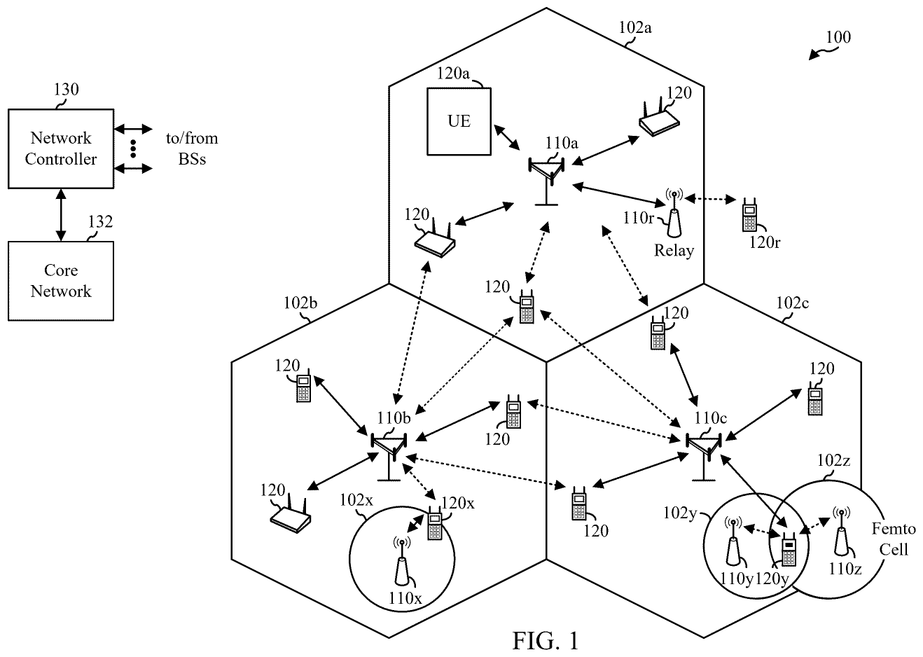

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, an augmented reality device, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to Nan, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include at least one filter circuit (e.g., a single-amplifier twin-T notch filter circuit) with independent control of filter gain and quality factor (Q), as described in more detail herein.

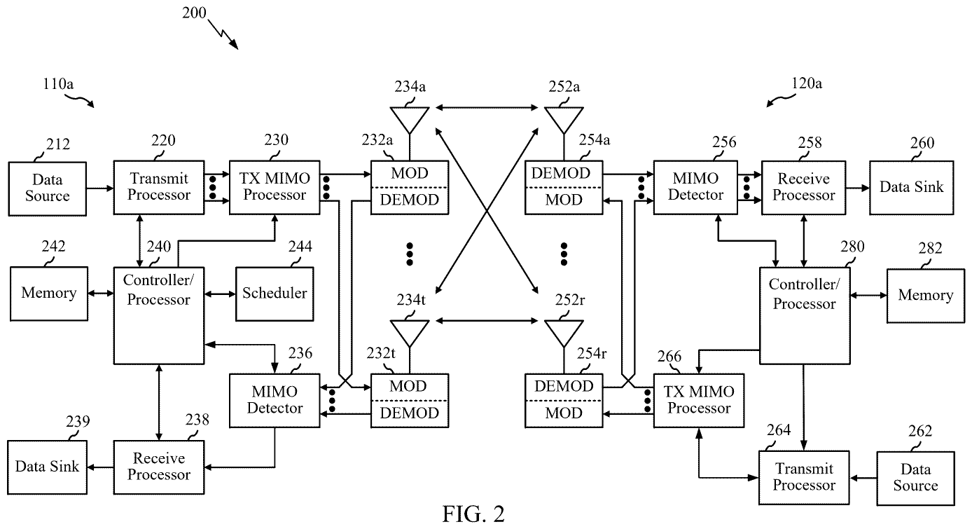

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232a-232t and/or the transceivers 254a-254r may include at least one filter circuit (e.g., a single-amplifier twin-T notch filter circuit) with independent control of filter gain and Q, as described in more detail herein.

### Example RF Transceiver

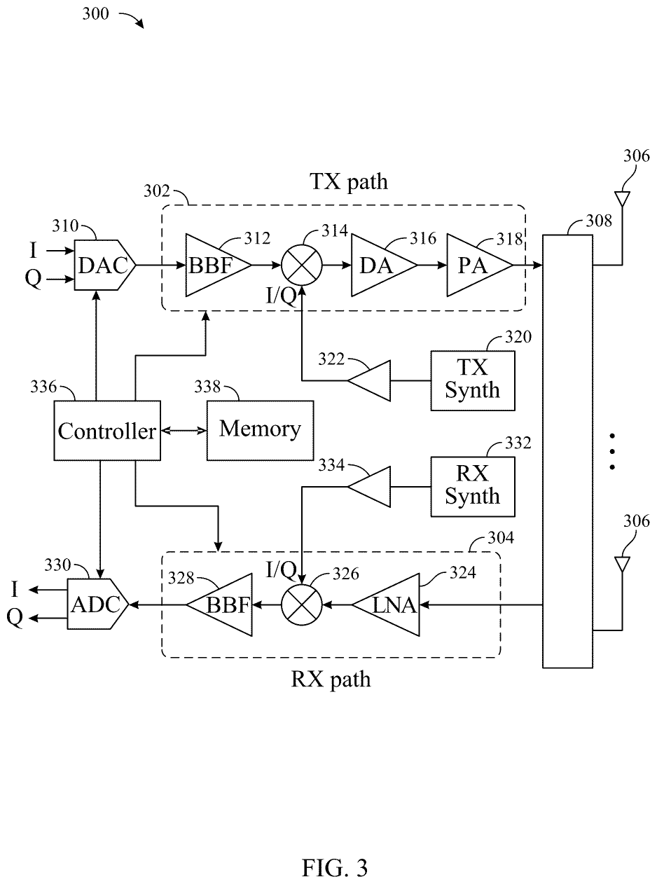

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320 with a transmit phase-locked loop (TxPLL). The transmit LO may be buffered or amplified by amplifier 322 before being mixed with the baseband signals in the mixer 314. Similarly, the receive LO may be produced by an RX frequency synthesizer 332 with a receive phase-locked loop (RxPLL). The receive LO may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

In certain aspects, at least one filter circuit (e.g., a single-amplifier twin-T notch filter circuit) with independent control of filter gain and Q as described herein may be included, for example, between the BBF 328 and the LNA 324 in the RX path 304 or in the BBF 328.

While FIGS. 1-3 provide wireless communications as an example application in which certain aspects of the present disclosure may be implemented to facilitate understanding, certain aspects described herein may be used in any of various other suitable systems.

### Example Filter Circuits and Operation

Certain wireless communication systems, such as Fifth Generation (5G) New Radio (NR), may support carrier aggregation (CA), including contiguous CA and non-contiguous CA. In contiguous CA, multiple available component carriers (CCs) are adjacent to each other. In non-contiguous CA, multiple available CCs are separated in a frequency band. Both non-contiguous and contiguous CA aggregate multiple CCs to serve a single wireless device, such as a user equipment (UE), as an illustrative example.

In some cases, a wireless device operating in a multicarrier system (e.g., a system supporting CA) can be configured to aggregate certain functions of multiple carriers, such as control and feedback functions, on a single carrier, which may be referred to as the primary component carrier (PCC). The remaining associated carriers that depend on the PCC for support may be referred to as the secondary component carriers (SCCs).

One potential challenge with operating in a multicarrier system is that there may be a low frequency separation between the PCC within the transmit (TX) frequency band and the SCC within the receive (RX) frequency band (commonly referred to as a “TX-RX gap”) in certain CA scenarios (e.g., certain non-contiguous CA scenarios, such as n25 TX band+n25 RX band). This low TX-RX gap can lead to the RX chain of a wireless device being impacted by strong jamming signals, which may be caused, for example, by radio emissions in nearby bands, such as radio transmissions from the wireless device in the TX frequency band for CA.

In some cases, analog filters (e.g., low-pass filters) may be utilized in an RX path (e.g., RX path 304) of a wireless device operating in a multicarrier system. However, some low-pass filters may be unable to reject the jamming signals that arise from the low TX-RX gap without degrading other parameters of the wireless device and/or the multicarrier system. Thus, some wireless devices may use a notch filter (e.g., in the RX path) to handle the jamming signals. For example, an active inductor (L) may be used to form a high quality factor (Q) inductor-capacitor (LC) notch filter. However, such high-Q LC notch filters may not be sufficiently reliable (e.g., due to their nonlinear nature, as well as the reliance on the transconductance (gₘ) of active devices). Furthermore, such high-Q LC notch filters may not be sufficiently compact (i.e., low area) and/or power efficient.

In certain aspects, a twin-T notch (TTN) filter may be used for jammer (or other frequency) rejection in wireless devices (e.g., included between a baseband filter (BBF) and a low noise amplifier (LNA) in an RX path of a wireless device, or included in the BBF of a wireless device) operating in a multicarrier system. The most area efficient implementation of the TTN filter may include (or be used in conjunction with) a single amplifier. The TTN filter may be considered essentially an active resistor-capacitor (RC) filter. When the bandwidth of the amplifier (e.g., op-amp) used in the TTN filter circuit is sufficiently wide, the performance of the filter circuit may be set by the accuracy of the resistors and capacitors therein.

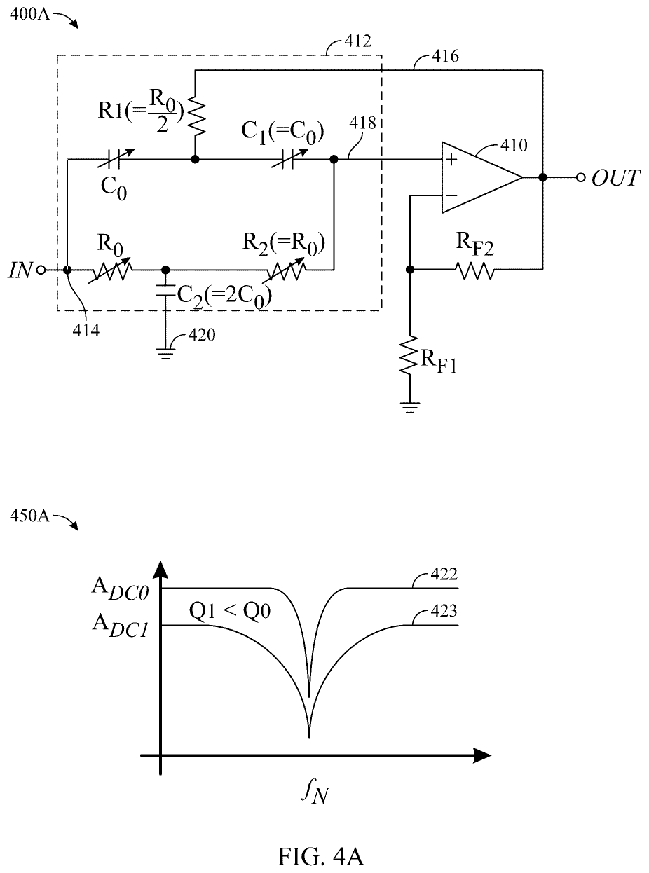

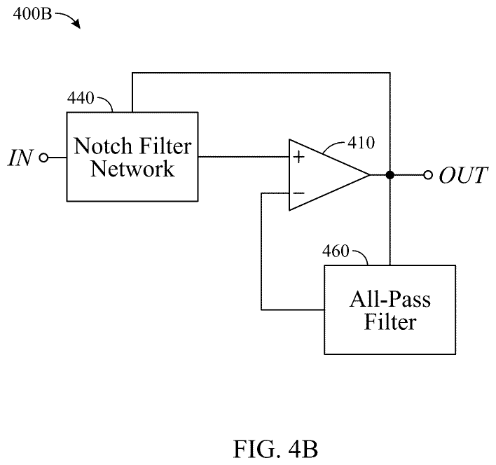

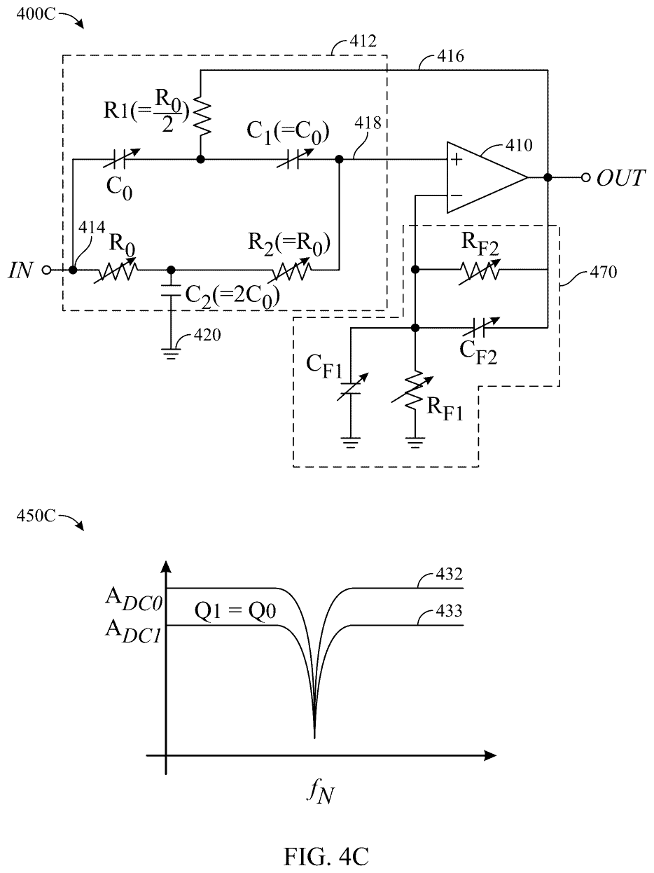

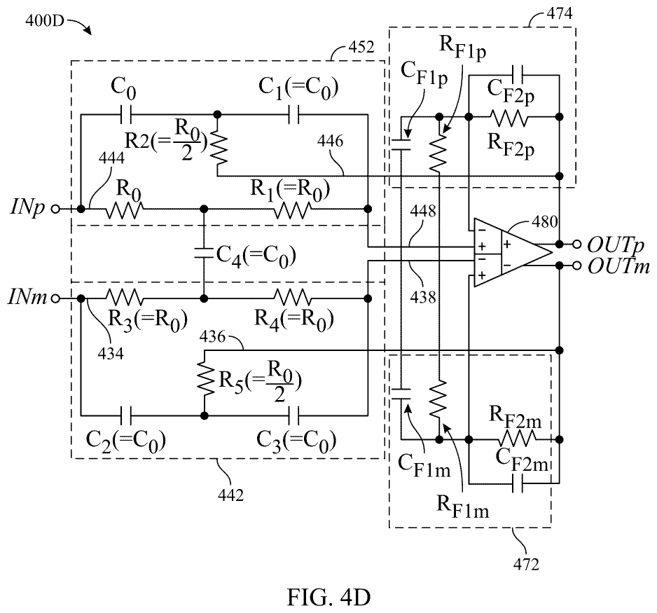

FIG. 4A is a schematic diagram of an example filter circuit 400A that includes an amplifier (e.g., amplifier 410) and a twin-T notch (TTN) filter 412, in accordance with certain aspects of the present disclosure. The TTN filter 412 may include a first node 414 coupled to an input node (labeled “IN”) of the filter circuit 400A, a second node 416 coupled to the output of the amplifier 410 and an output node (labeled “OUT”) of the filter circuit 400A, and a third node 418 coupled to a first input (e.g., the positive input) of the amplifier 410.

The TTN filter 412 may include resistive elements R₀, R₁, and R₂ and capacitive elements C₀, C₁, and C₂. The resistive element R₀ may include a first terminal coupled to the first node 414 of the TTN filter 412 and a second terminal coupled to a first terminal of the capacitive element C₂. A second terminal of the capacitive element C₂ may be coupled to a reference potential node 420 (e.g., electrical ground) for the filter circuit 400A. The resistive element R₂ may include a first terminal coupled to the first terminal of the capacitive element C₂ and a second terminal coupled to the third node 418. The first capacitive element C₀ may include a first terminal coupled to the first node 414 and a second terminal coupled to a first terminal of resistive element R₁. The resistive element R₁ may include a second terminal coupled to the second node 416. The capacitive element C₁ may include a first terminal coupled to the first terminal of resistive element R₁ and a second terminal coupled to the third node 418. As illustrated in FIG. 4A, the resistive element R₂ may have the same nominal resistance as the resistive element R₀, whereas the resistive element R₁ may have half the nominal resistance as the resistive element R₀. Also as illustrated in FIG. 4A, the capacitive element C₁ may have the same nominal capacitance as the capacitive element C₀, whereas the capacitive element C₂ may have double the nominal capacitance as the capacitive element C₀. In some cases, one or more of the resistive elements R₀, R₁, and R₂ may be implemented by adjustable resistive elements, and/or one or more of the capacitive elements C₀, C₁, and C₂ may be implemented as adjustable capacitive elements.

The negative feedback network of the filter circuit 400A may include a resistive element R_{RF1} and a resistive element R_{RF2}. Resistive element R_{RF2} may include a first terminal coupled to a second input (e.g., the negative input) of the amplifier 410 and a second terminal coupled to the output of the amplifier 410 and the OUT node of the filter circuit 400A. Resistive element R_{RF1} may include a first terminal coupled to the first terminal of the resistive element R_{RF2} and a second terminal coupled to the reference potential node 420.

The filter transfer function of the filter circuit 400A may be expressed by the equation shown below:

$$\frac{{V}_{OUT}}{{V}_{IN}} = \frac{( 1 + \frac{{R}_{F 2}}{{R}_{F 1}} ) ( {S}^{2} + \frac{1}{{( {R}_{0} {C}_{0} )}^{2}} )}{{S}^{2} + \frac{2}{{R}_{0} {C}_{0}} ( 1 + \frac{{R}_{F 2}}{{R}_{F 1}} ) S + \frac{1}{{( {R}_{0} {C}_{0} )}^{2}}}$$

where the S represents a complex number frequency parameter of the Laplace transform, and where R₀, R_{F1}, R_{F2}, and C₀, represent resistance/capacitance values corresponding to the resistive elements R₀, R_{F1}, and R_{F2} and the capacitive element C₀ illustrated in FIG. 4A.

The DC filter gain (A_{DC}), filter Q, and notch frequency (F_{N}) of the filter circuit 400A may be represented by the equations shown below:

$${A}_{D C} = 1 + \frac{{R}_{F 2}}{{R}_{F 1}}$$

$$Q = \frac{1}{2 ( 2 - {A}_{D C} )}$$

$${F}_{N} = \frac{1}{2 π {R}_{0} {C}_{0}}$$

where R₀, R_{F1}, R_{F2}, and C₀, represent resistance/capacitance values corresponding to the resistive elements R₀, R_{F1}, and R_{F2} and the capacitive element C₀ illustrated in FIG. 4A.

As illustrated in the equations shown above, the filter Q (e.g., filtering profile) of the filter circuit 400A depends on the DC filter gain (e.g., as a result of the negative feedback network (i.e., the resistive elements R_{F1} and R_{F2}) having the same behavior at high and low frequencies). As such, any change to the gain of the filter circuit 400A also changes the Q of the filter circuit 400A, and the filter gain may not be optimized without negatively impacting the filter Q. FIG. 4A also includes a graph 450A illustrating example frequency responses 422 and 423 of the filter circuit 400A. When operating with the filter gain A_{DC0}, the filter circuit 400A may produce the frequency response 422 and have a Q equal to Q₀. When operating with the filter gain A_{DC1}, the filter circuit 400A may produce the frequency response 423 and have a Q equal to Q₁. As illustrated, the Q of the filter circuit 400A may decrease (e.g., such that Q₁<Q₀) when the filter gain decreases (e.g., from A_{DC0} to A_{DC1}), resulting in a widening of the notch of the filter circuit 400A.

Certain aspects of the present disclosure are directed to a filter circuit (e.g., a single-amplifier twin-T notch filter circuit) with independent control of filter gain and Q (e.g., for including in wireless receiver circuitry). Such a filter circuit may include an amplifier (e.g., a single amplifier), a notch filter network (e.g., a TTN filter), and an all-pass filter (e.g., for the negative feedback network). In this manner, the filter gain and the filter Q may be decoupled, thereby enabling independent control of the gain and the Q of the filter circuit. The filter circuit may be, for example, included between a BBF (e.g., BBF 328) and an LNA (e.g., LNA 324) in an RX path (e.g., RX path 304) of a wireless device, or included in the BBF of a wireless device to improve device operation. For example, when implemented with a TTN filter, the filter circuit may be tunable for different notch frequencies and process controlled. Furthermore, the filter circuit described herein may also increase jamming signal rejection for a wireless device in multicarrier systems, improve process/temperature variation of the notch of the TTN filter, reduce band-edge droop of the BBF of a wireless device, and/or allow for increased filter optimization to improve noise and linearity.

FIG. 4B is a block diagram of an example filter circuit 400B (which may also be referred to as a notch filter circuit) that includes an amplifier (e.g., the amplifier 410), a notch filter network 440, and an all-pass filter 460, in accordance with certain aspects of the present disclosure. The filter circuit 400B may include an input node (labeled “IN”) coupled to the notch filter network 440 and include an output node (labeled “OUT”) coupled to an output of the amplifier 410 and the notch filter network 440. The notch filter network 440 may also be coupled to a first input (e.g., the positive input) of the amplifier 410. The all-pass filter 460 may be coupled between a second input (e.g., the negative input) of the amplifier 410 and the output of the amplifier 410 (e.g., forming a negative feedback loop). In certain aspects, the notch filter network 440 may be implemented with a TTN filter (e.g., the TTN filter 412).

FIG. 4C is a schematic diagram of an example filter circuit 400C that includes the amplifier 410, the TTN filter 412, and an all-pass filter 470, in accordance with certain aspects of the present disclosure. The filter circuit 400C may be similar to the filter circuit 400A. As such, the TTN filter 412 may be coupled to an input node (labeled “IN”) of the filter circuit 400C, to the reference potential node 420, to a first input (e.g., the positive input) of the amplifier 410, and to an output node (labeled “OUT”) of the filter circuit 400C, as illustrated. However, in contrast to the filter circuit 400A, the filter circuit 400C may include the all-pass filter 470 coupled between a second input (e.g., the negative input) of the amplifier 410 and the OUT node of the filter circuit 400C (as opposed to just the resistive elements R_{F1} and R_{F2} of the filter circuit 400A). In this manner, the all-pass filter 470 may be used in the negative feedback network of the amplifier 410 in the filter circuit 400C.

The all-pass filter 470 may include resistive elements R_{F1} and R_{F2} and capacitive elements C_{F1} and C_{F2}, as illustrated. The resistive element R_{F2} may include a first terminal coupled to the negative input of the amplifier 410 and include a second terminal coupled to the output of the amplifier 410. The capacitive element C_{F2} may be coupled in parallel with the resistive element R_{F2} and, thus, may include a first terminal coupled to the negative input of the amplifier 410 and include a second terminal coupled to the output of the amplifier 410. The resistive element R_{F1} may include a first terminal coupled to the first terminal of the capacitive element C_{F2} and include a second terminal coupled to the reference potential node 420 for the filter circuit 400C. The capacitive element C_{F1} may be coupled in parallel with the resistive element R_{F1} and, thus, may include a first terminal coupled to the first terminal of the capacitive element C_{F2} and include a second terminal coupled to the reference potential node 420. In some cases, one or more of the resistive element R_{F1} and R_{F2} may be implemented with adjustable resistive elements, and/or one or more of the capacitive elements C_{F1} and C_{F2} may be implemented with adjustable capacitive elements.

The filter transfer function of the filter circuit 400C may be expressed by the equation shown below:

$$\frac{{V}_{OUT}}{{V}_{IN}} = \frac{( 1 + \frac{{R}_{F 2}}{{R}_{F 1}} ) ( {S}^{2} + \frac{1}{{( {R}_{0} {C}_{0} )}^{2}} )}{{S}^{2} + \frac{2}{{R}_{0} {C}_{0}} ( 1 + \frac{{R}_{F 2}}{{R}_{F 1}} ) S + \frac{1}{{( {R}_{0} {C}_{0} )}^{2}}}$$

where the S represents a complex number frequency parameter of the Laplace transform, where R₀ and C₀ represent resistance/capacitance values corresponding to the resistive element R₀ and the capacitive element C₀ in the filter circuit 400C, where Z_{F1} represents the impedance associated with R_{F1} and C_{F1} of the all-pass filter 470, and where Z_{F2} represents the impedance associated with R_{F2} and C_{F2} of the all-pass filter 470. Z_{F1} and Z_{F2} may be expressed by the Z_{F} equation shown below (e.g., by substituting Z_{F} with Z_{F1} or Z_{F2}, RF with R_{F1} or R_{F2}, and CF with R_{F1} or R_{F2}, respectively).

The impedance (Z_{F}), DC filter gain (A_{DC}), and Q of the filter circuit 400C may be represented by the equations shown below:

$${Z}_{F} = \frac{{R}_{F}}{1 + {R}_{F} {C}_{F} S} \to \{ \begin{matrix}{A}_{DC} ( low freq ) = 1 + \frac{{R}_{F 2}}{{R}_{F 1}} \\ Q ( high freq ) \approx \frac{1}{2 ( 1 - \frac{{C}_{F 1}}{{C}_{F 2}} )}\end{matrix}$$

where R_{F}, R_{F1}, R_{F2}, C_{F}, C_{F1}, and C_{F2} represent resistance/capacitance values corresponding to the resistive elements R_{F}, R_{F1}, and R_{F2} and the capacitive elements C_{F}, C_{F1}, and C_{F2} in the filter circuit 400C. As can be gleaned from the equations, the inclusion of the all-pass filter 470 allows the DC filter gain (at low frequencies) to be decoupled from the rejection band Q (at high frequencies), which enables the gain and Q of the filter circuit 400C to be controlled independently, namely, by adjusting the resistance values of R_{F1} and/or R_{F2} and the capacitance values of C_{F1} and/or C_{F2}.

FIG. 4C also includes a graph 450C illustrating example frequency responses 432 and 433 of the filter circuit 400C. When operating with the filter gain A_{DC0}, the filter circuit 400C may produce the frequency response 432 and have a Q equal to Q₀. When operating with the filter gain A_{DC1}, the filter circuit 400C may produce the frequency response 433 and have a Q equal to Q₁. As illustrated, the Q of the filter circuit 400C may be equal (e.g., such that Q₁=Q₀) even as the filter gain decreases (e.g., from A_{DC0} to A_{DC1}). In this manner, and as expressed by the equations shown above, the (e.g., low frequency) DC gain of the filter circuit 400C may be controlled independent of the (e.g., high frequency) Q of the filter circuit 400C (e.g., by adjusting resistive elements R_{F1} and/or R_{F2} and/or adjusting capacitive elements C_{F1} and/or C_{F2}).

FIG. 4D is a schematic diagram of an example differential filter circuit 400D that includes a differential amplifier (e.g., differential amplifier 480), two TTN filters (e.g., TTN filter 442 and TTN filter 452), and two all-pass filters (e.g., all-pass filter 472 and all-pass filter 474), in accordance with certain aspects of the present disclosure. The filter circuit 400D may enable independent control of filter gain and Q, similar to the filter circuit 400C (e.g., by adjusting the resistive elements and/or capacitive elements in the TTN filter 442 and TTN filter 452). The filter circuit 400D may be similar to the filter circuit 400C. However, the amplifier 410 may be replaced by the differential amplifier 480, and the filter circuit 400D may include an additional TTN filter 452 and an additional all-pass filter 474. The TTN filters 442 and 452 may be similar to the TTN filter 412, and the all-pass filters 472 and 474 may be similar to the all-pass filter 470.

The filter circuit 400D may include a first input node (labeled “INm” for “minus input”) and a second input node (labeled “INp” for “plus input”), which form a differential input pair. The filter circuit 400D may also include a first output node (labeled “OUTm” for “minus output”) and a second input node (labeled “OUTp” for “plus output”), which form a differential output pair. The TTN filter 442 may include a first node 434 coupled to the INp node of the filter circuit 400C, a second node 436 coupled to a first output of the differential amplifier 480 and to the OUTm node of the filter circuit 400D, and a third node 438 coupled to a first input (e.g., a first negative input) of the differential amplifier 480.

The TTN filter 442 may include resistive elements R₃, R₄, and R₅ and capacitive elements C₂, C₃, and C₄. The resistive element R₃ may include a first terminal coupled to the first node 434 and a second terminal coupled to a first terminal of capacitive element C₄. The second terminal of the capacitive element C₄ may be coupled to the TTN filter 452. In this manner, the capacitive element C₄ may be effectively shared and be a part of both the TTN filter 442 and the TTN filter 452. The resistive element R₄ may include a first terminal coupled to the first terminal of the capacitive element C₄ and a second terminal coupled to the third node 438. The first capacitive element C₂ may include a first terminal coupled to the first node 434 and a second terminal coupled to a first terminal of resistive element R₅. The resistive element R₅ may include a second terminal coupled to the second node 436. The capacitive element C₃ may include a first terminal coupled to the first terminal of resistive element R₅ and a second terminal coupled to the third node 438. In some cases, one or more of the resistive elements R₃, R₄, and R₅ may be implemented by adjustable resistive elements, and/or one or more of the capacitive elements C₂, C₃, and C₄ may be implemented as adjustable capacitive elements.

The TTN filter 452 may include a first node 444 coupled to the INp node of the filter circuit 400C, a second node 446 coupled to a second output of the differential amplifier 480 and to the OUTp node of the filter circuit 400D, and a third node 448 coupled to a second input (e.g., a first positive input) of the differential amplifier 480.

The TTN filter 452 may include resistive elements R₀, R₁, and R₂ and capacitive elements C₀, C₁, and C₄. The resistive element R₀ may include a first terminal coupled to the first node 444 and a second terminal coupled to the second terminal of the capacitive element C₄. The resistive element R₁ may include a first terminal coupled to the second terminal of the capacitive element C₄ and a second terminal coupled to the third node 448. The capacitive element C₀ may include a first terminal coupled to the first node 444 and a second terminal coupled to a first terminal of the resistive element R₂. The resistive element R₂ may include a second terminal coupled to the second node 446. The capacitive element C₁ may include a first terminal coupled to the first terminal of resistive element R₂ and a second terminal coupled to the third node 448. In some cases, one or more of the resistive elements R₀, R₁, and R₂, may be implemented by adjustable resistive elements, and/or one or more of the capacitive elements C₀, C₁, and C₄ may be implemented as adjustable capacitive elements.

As illustrated in FIG. 4D, the resistive elements R₁, R₃, and R₄ may have the same nominal resistance as the resistive element R₀, whereas the resistive elements R₂ and R₅ may have half the nominal resistance as the resistive element R₀. Also as illustrated in FIG. 4D, the capacitive elements C₁, C₂, C₃, and C₄ may have the same nominal capacitance as the capacitive element C₀.

The all-pass filter 472 may include resistive elements R_{F1m} and R_{F2m} and capacitive elements C_{F1m} and C_{F2m}, as illustrated. The resistive element R_{F2m} may include a first terminal coupled to a third input (e.g., a second positive input) of the differential amplifier 480 and include a second terminal coupled to the first output of the differential amplifier 480 and to the OUTm node. The capacitive element C_{F2m} may be coupled in parallel with the resistive element R_{F2m} and, thus, may include a first terminal coupled to the third input of the differential amplifier 480 and include a second terminal coupled to the first output of the differential amplifier 480 and to the OUTm node. The resistive element R_{F1m} may include a first terminal coupled to the first terminal of the resistive element R_{F2m} and include a second terminal coupled to the all-pass filter 474. The capacitive element C_{F1m} may be coupled in parallel with the resistive element R_{F1m} and, thus, may include a first terminal coupled to the first terminal of the resistive element R_{F1m} and include a second terminal coupled to the all-pass filter 474. In some cases, one or more of resistive elements R_{F1m} and R_{F2m} may be implemented with adjustable resistive elements, and/or one or more of capacitive elements C_{F1m} and C_{F2m} may be implemented with adjustable capacitive elements.

The all-pass filter 474 may include resistive elements R_{F1p} and R_{F2p} and capacitive elements C_{F1p} and C_{F2p}, as illustrated. The resistive element R_{F2p} may include a first terminal coupled to a fourth input (e.g., a second negative input) of the differential amplifier 480 and include a second terminal coupled to the second output of the differential amplifier 480 and to the OUTp node. The capacitive element C_{F2p} may be coupled in parallel with the resistive element R_{F2p} and, thus, may include a first terminal coupled to the fourth input of the differential amplifier 480 and include a second terminal coupled to the second output of the differential amplifier 480 and to the OUTp node. The resistive element R_{F1p} may include a first terminal coupled to the first terminal of the resistive element R_{F2p} and include a second terminal coupled to the second terminal of the resistive element R_{F1} m. The capacitive element C_{F1p} may be coupled in parallel with the resistive element R_{F1p} and, thus, may include a first terminal coupled to the first terminal of the resistive element R_{F2p} and include a second terminal coupled to the second terminal of the capacitive element C_{F1m}. In some cases, one or more of resistive elements R_{F1p} and R_{F2p} may be implemented with adjustable resistive elements, and/or one or more of capacitive elements C_{F1p} and C_{F2p} may be implemented with adjustable capacitive elements.

### Example Operations for Signal Processing

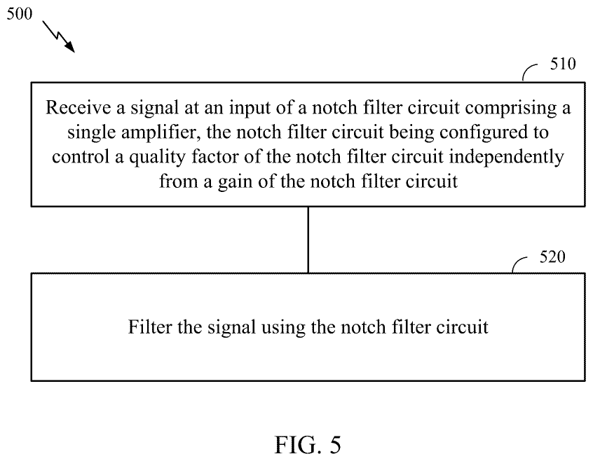

FIG. 5 is a flow diagram illustrating example operations 500 for signal processing, in accordance with certain aspects of the present disclosure. The operations 500 may be performed, for example, by a filter circuit, such as filter circuit 400B of FIG. 4B, filter circuit 400C of FIG. 4C, or filter circuit 400D of FIG. 4D.

The operations 500 may include, at block 510, receiving a signal at an input (e.g., the input labeled “IN,” labeled “INp,” or labeled “INm”) of a notch filter circuit (e.g., filter circuit 400B, filter circuit 400C, or filter circuit 400D) that may include a single amplifier (e.g., amplifier 410 or differential amplifier 480). The notch filter circuit may be configured to control a quality factor of the notch filter circuit independently from a gain of the notch filter circuit.

At block 520, the operations 500 may include filtering the signal using the notch filter circuit. In some cases, the filtering at block 520 may include filtering a first signal using a first gain for the notch filter circuit with a first filter response having a first quality factor (Q). In these cases, the operations 500 may further include (i) adjusting the gain of the notch filter circuit to a second gain, the second gain being different from the first gain, and (ii) filtering a second signal using the second gain for the notch filter circuit with a second filter response having a second Q, the second Q being substantially equal to the first Q.

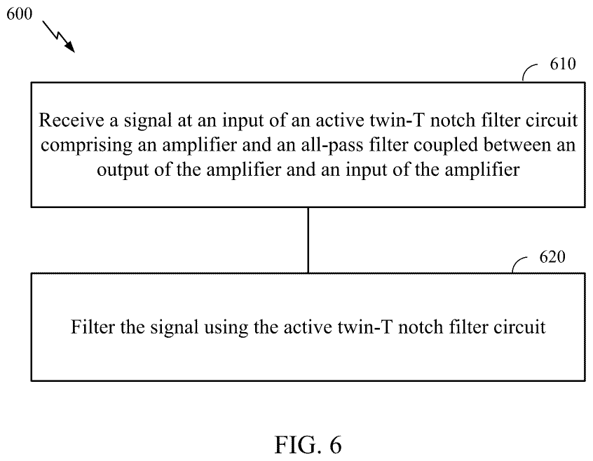

FIG. 6 is a flow diagram illustrating example operations 600 for signal processing, in accordance with certain aspects of the present disclosure. The operations 600 may be performed, for example, by a filter circuit, such as filter circuit 400B of FIG. 4B, filter circuit 400C of FIG. 4C, or filter circuit 400D of FIG. 4D.

The operations 600 may include, at block 610, receiving a signal at an input (e.g., the input labeled “IN,” labeled “INp,” or labeled “INm”) of an active twin-T notch filter circuit (e.g., twin-T notch (TTN) filter 412, notch filter network 440, TTN filter 442, or TTN filter 452) that may include an amplifier (e.g., amplifier 410 or differential amplifier 480) and an all-pass filter (e.g., all-pass filter 460, all-pass filter 470, all-pass filter 472, or all-pass filter 474) coupled between an output of the amplifier and an input of the amplifier.

At block 620, the operations 600 may include filtering the signal using the active twin-T notch filter circuit. In some cases, the filtering at block 620 may include filtering a first signal using a first gain for the active twin-T notch filter circuit with a first filter response having a first Q. In these cases, the operations 600 may further include (i) adjusting a gain of the active twin-T notch filter circuit to a second gain, the second gain being different from the first gain, and (ii) filtering a second signal using the second gain for the active twin-T notch filter circuit with a second filter response having a second Q, the second Q being substantially equal to the first Q.

### EXAMPLE ASPECTS

In addition to the various aspects described above, specific combinations of aspects are within the scope of the present disclosure, some of which are detailed below:

Aspect 1: A filter circuit comprising: an input node; an output node; an amplifier including an output coupled to the output node of the filter circuit; a twin-T notch filter including a first node coupled to the input node of the filter circuit, a second node coupled to the output of the amplifier, and a third node coupled to a first input of the amplifier; and an all-pass filter coupled between the output of the amplifier and a second input of the amplifier.

Aspect 2: The filter circuit of Aspect 1, wherein the all-pass filter comprises: a first resistive element including a first terminal coupled to the second input and including a second terminal coupled to the output of the amplifier; and a first capacitive element including a first terminal coupled to the second input and including a second terminal coupled to the output of the amplifier.

Aspect 3: The filter circuit of Aspect 2, wherein the first resistive element comprises a first adjustable resistive element.

Aspect 4: The filter circuit of Aspect 3, wherein the first capacitive element comprises a first adjustable capacitive element.

Aspect 5: The filter circuit of Aspect 4, wherein the all-pass filter further comprises: a second resistive element including a first terminal coupled to the first terminal of the first capacitive element and including a second terminal coupled to a reference potential node for the filter circuit; and a second capacitive element including a first terminal coupled to the first terminal of the first capacitive element and including a second terminal coupled to the reference potential node.

Aspect 6: The filter circuit of Aspect 5, wherein at least one of: the second resistive element comprises a second adjustable resistive element; or the second capacitive element comprises a second adjustable capacitive element.

Aspect 7: The filter circuit according to any of Aspects 2 or 3, wherein the first capacitive element comprises an adjustable capacitive element.

Aspect 8: The filter circuit of Aspect 2, wherein the all-pass filter further comprises: a second resistive element including a first terminal coupled to the first terminal of the first capacitive element and including a second terminal coupled to a reference potential node for the filter circuit; and a second capacitive element including a first terminal coupled to the first terminal of the first capacitive element and including a second terminal coupled to the reference potential node.

Aspect 9: The filter circuit of Aspect 8, wherein at least one of the first resistive element, the second resistive element, the first capacitive element, or the second capacitive element is adjustable.

Aspect 10: The filter circuit of Aspect 8 or 9, wherein the twin-T notch filter comprises: a third resistive element including a first terminal coupled to the first node of the twin-T notch filter; a fourth resistive element including a first terminal coupled to the third node of the twin-T notch filter; a third capacitive element including a first terminal coupled to a second terminal of the third resistive element and to a second terminal of the fourth resistive element and including a second terminal coupled to the reference potential node; a fourth capacitive element including a first terminal coupled to the first node of the twin-T notch filter; a fifth capacitive element including a first terminal coupled to the third node of the twin-T notch filter; and a fifth resistive element including a first terminal coupled to a second terminal of the fourth capacitive element and to a second terminal of the fifth capacitive element and including a second terminal coupled to the second node of the twin-T notch filter.

Aspect 11: The filter circuit of Aspect 10, wherein at least one of: the third resistive element comprises a first adjustable resistive element; the fourth resistive element comprises a second adjustable resistive element; the third capacitive element comprises a first adjustable capacitive element; the fourth capacitive element comprises a second adjustable capacitive element; the fifth capacitive element comprises a third adjustable capacitive element; and the fourth resistive element comprises a third adjustable resistive element.

Aspect 12: The filter circuit according to any of Aspects 1-11, further comprising: another input node, wherein the input node and the other input node form a differential input pair; another output node, wherein the output node and the other output node form a differential output pair; another twin-T notch filter including a first node coupled to the other input node of the filter circuit, a second node coupled to another output of the amplifier, and a third node coupled to a third input of the amplifier; and another all-pass filter coupled between the other output of the amplifier and a fourth input of the amplifier, wherein the amplifier comprises a differential amplifier.

Aspect 13: A notch filter circuit comprising a single amplifier, the notch filter circuit being configured to independently control a quality factor of the notch filter circuit and a gain of the notch filter circuit.

Aspect 14: The notch filter circuit of Aspect 13, further comprising an all-pass filter coupled between an input of the amplifier and an output of the amplifier.

Aspect 15: The notch filter circuit of Aspect 14, wherein the all-pass filter comprises: a first resistive element including a first terminal coupled to the input of the amplifier and including a second terminal coupled to the output of the amplifier; and a first capacitive element including a first terminal coupled to the input of the amplifier and including a second terminal coupled to the output of the amplifier.

Aspect 16: The notch filter circuit of Aspect 15, wherein: the first resistive element comprises a first adjustable resistive element; and the first capacitive element comprises a first adjustable capacitive element.

Aspect 17: The notch filter circuit of Aspect 15 or 16, wherein the all-pass filter further comprises a second resistive element including a first terminal coupled to the first terminal of the first capacitive element and including a second terminal coupled to a reference potential node for the notch filter circuit; and a second capacitive element including a first terminal coupled to the first terminal of the first capacitive element and including a second terminal coupled to the reference potential node.

Aspect 18: The notch filter circuit of Aspect 17, wherein at least two of the first resistive element, the second resistive element, the first capacitive element, or the second capacitive element are adjustable.

Aspect 19: The notch filter circuit according to any of Aspects 14-18, wherein the notch filter circuit comprises a twin-T notch filter circuit.

Aspect 20: A method of signal processing, comprising: receiving a signal at an input of a notch filter circuit comprising a single amplifier, the notch filter circuit being configured to control a quality factor of the notch filter circuit independently from a gain of the notch filter circuit; and filtering the signal using the notch filter circuit.

Aspect 21: The method of Aspect 20, wherein the filtering comprises filtering a first signal using a first gain for the notch filter circuit with a first filter response having a first quality factor (Q) and wherein the method further comprises: adjusting the gain of the notch filter circuit to a second gain, the second gain being different from the first gain; and filtering a second signal using the second gain for the notch filter circuit with a second filter response having a second Q, the second Q being substantially equal to the first Q.

Aspect 22: A method of signal processing, comprising: receiving a signal at an input of an active twin-T notch filter circuit comprising an amplifier and an all-pass filter coupled between an output of the amplifier and an input of the amplifier; and filtering the signal using the active twin-T notch filter circuit.

Aspect 23: The method of Aspect 22, wherein the filtering comprises filtering a first signal using a first gain for the active twin-T notch filter circuit with a first filter response having a first quality factor (Q) and wherein the method further comprises: adjusting a gain of the active twin-T notch filter circuit to a second gain, the second gain being different from the first gain; and filtering a second signal using the second gain for the active twin-T notch filter circuit with a second filter response having a second Q, the second Q being substantially equal to the first Q.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A filter circuit comprising:
an input node;
an output node;
an amplifier including an output coupled to the output node of the filter circuit;
a twin-T notch filter including a first node coupled to the input node of the filter circuit, a second node coupled to the output of the amplifier, and a third node coupled to a first input of the amplifier; and
an all-pass filter coupled between the output of the amplifier and a second input of the amplifier.

2. The filter circuit of claim 1, wherein the all-pass filter comprises:
a first resistive element including a first terminal coupled to the second input and including a second terminal coupled to the output of the amplifier; and
a first capacitive element including a first terminal coupled to the second input and including a second terminal coupled to the output of the amplifier.

3. The filter circuit of claim 2, wherein the first resistive element comprises a first adjustable resistive element.

4. The filter circuit of claim 3, wherein the first capacitive element comprises a first adjustable capacitive element.

5. The filter circuit of claim 4, wherein the all-pass filter further comprises:
a second resistive element including a first terminal coupled to the first terminal of the first capacitive element and including a second terminal coupled to a reference potential node for the filter circuit; and
a second capacitive element including a first terminal coupled to the first terminal of the first capacitive element and including a second terminal coupled to the reference potential node.

6. The filter circuit of claim 5, wherein at least one of:
the second resistive element comprises a second adjustable resistive element; or
the second capacitive element comprises a second adjustable capacitive element.

7. The filter circuit of claim 2, wherein the first capacitive element comprises an adjustable capacitive element.

8. The filter circuit of claim 2, wherein the all-pass filter further comprises:
a second resistive element including a first terminal coupled to the first terminal of the first capacitive element and including a second terminal coupled to a reference potential node for the filter circuit; and
a second capacitive element including a first terminal coupled to the first terminal of the first capacitive element and including a second terminal coupled to the reference potential node.

9. The filter circuit of claim 8, wherein at least one of the first resistive element, the second resistive element, the first capacitive element, or the second capacitive element is adjustable.

10. The filter circuit of claim 8, wherein the twin-T notch filter comprises:
a third resistive element including a first terminal coupled to the first node of the twin-T notch filter;
a fourth resistive element including a first terminal coupled to the third node of the twin-T notch filter;
a third capacitive element including a first terminal coupled to a second terminal of the third resistive element and to a second terminal of the fourth resistive element and including a second terminal coupled to the reference potential node;
a fourth capacitive element including a first terminal coupled to the first node of the twin-T notch filter;
a fifth capacitive element including a first terminal coupled to the third node of the twin-T notch filter; and
a fifth resistive element including a first terminal coupled to a second terminal of the fourth capacitive element and to a second terminal of the fifth capacitive element and including a second terminal coupled to the second node of the twin-T notch filter.

11. The filter circuit of claim 10, wherein at least one of:
the third resistive element comprises a first adjustable resistive element;
the fourth resistive element comprises a second adjustable resistive element;
the third capacitive element comprises a first adjustable capacitive element;
the fourth capacitive element comprises a second adjustable capacitive element;
the fifth capacitive element comprises a third adjustable capacitive element; and
the fourth resistive element comprises a third adjustable resistive element.

12. The filter circuit of claim 1, further comprising:
another input node, wherein the input node and the other input node form a differential input pair;
another output node, wherein the output node and the other output node form a differential output pair;
another twin-T notch filter including a first node coupled to the other input node of the filter circuit, a second node coupled to another output of the amplifier, and a third node coupled to a third input of the amplifier; and
another all-pass filter coupled between the other output of the amplifier and a fourth input of the amplifier, wherein the amplifier comprises a differential amplifier.

13. A notch filter circuit comprising a single amplifier, the notch filter circuit being configured to independently control a quality factor of the notch filter circuit and a gain of the notch filter circuit.

14. The notch filter circuit of claim 13, further comprising an all-pass filter coupled between an input of the amplifier and an output of the amplifier.

15. The notch filter circuit of claim 14, wherein the all-pass filter comprises:
a first resistive element including a first terminal coupled to the input of the amplifier and including a second terminal coupled to the output of the amplifier; and
a first capacitive element including a first terminal coupled to the input of the amplifier and including a second terminal coupled to the output of the amplifier.

16. The notch filter circuit of claim 15, wherein:
the first resistive element comprises a first adjustable resistive element; and
the first capacitive element comprises a first adjustable capacitive element.

17. The notch filter circuit of claim 15, wherein the all-pass filter further comprises
a second resistive element including a first terminal coupled to the first terminal of the first capacitive element and including a second terminal coupled to a reference potential node for the notch filter circuit; and
a second capacitive element including a first terminal coupled to the first terminal of the first capacitive element and including a second terminal coupled to the reference potential node.

18. The notch filter circuit of claim 17, wherein at least two of the first resistive element, the second resistive element, the first capacitive element, or the second capacitive element are adjustable.

19. The notch filter circuit of claim 14, wherein the notch filter circuit comprises a twin-T notch filter circuit.

20. A method of signal processing, comprising:
receiving a signal at an input of a notch filter circuit comprising a single amplifier, the notch filter circuit being configured to control a quality factor of the notch filter circuit independently from a gain of the notch filter circuit; and
filtering the signal using the notch filter circuit.
